(19) United States
(12) Patent Application Publication
(10) Pub. No.: US 2012/0039051 A1
(43) Pub. Date: Feb. 16, 2012

(54) WIRELESS NETWORK ADAPTER

(76) Inventor: Nai-Chien CHANG, New Taipei City (TW)

(21) Appl. No.: 13/149,775

(22) Filed: May 31, 2011

(30) Foreign Application Priority Data
Aug. 16, 2010 (TW) 099215705

(51) Int. Cl. H05K 5/00

(52) U.S. Cl. 361/752

(57) ABSTRACT

The wireless network adapter includes a circuit board, a wireless network module, a High Definition Multimedia Interface (HDMI) connector, and a housing. The wireless network module is electrically connected to the circuit board. The HDMI connector is electrically connected to the circuit board. The housing has a room for accommodating the circuit board, the wireless network module and a part of the HDMI connector and an opening for being protruded by the HDMI connector. The adapter can be connected to a host by the HDMI connector.

### BACKGROUND OF THE INVENTION

1. Technical Field

The invention relates to network adapters, particularly to wireless network adapters.

2. Related Art

In recent years, internet has become extremely popular all over the world. Almost all of portable electronic devices such as computers, mobile phones, personal digital assistants (PDAs), multimedia players, TV games and even digital cameras are capable of networking via wired or wireless paths. The networking capacity may extend functions or obtain on-line information.

For example, a computer is usually provided with a built-in network adapter or card. The network adapter or card must be connected by a cable. The cable limits mobility of the computer. As a result, wireless connection appears to replace wired connection.

Initially, wireless network adapters are made in a form of add-on card with PCI interface. With compactness of size of the wireless adapter and popularity of the universal serial bus (USB), USB adapters have become a primary product in the market.

However, almost all of external devices use USB to make a connection with a computer. Thus the number of USB ports may be insufficient when a user currently uses plural external devices. On the other hand, some of new interfaces are provided with network connection function, such as the HDMI (High Definition Multimedia Interface) version 1.4. Accordingly, a device which uses an interface other than USB will satisfy users' current requirement for sharing increasingly heavy load of USB. Also, the data transfer speed of network can be enhanced.

Modern LCD TV sets or displays are equipped with HDMI ports for accessing video with high definition. Usually, those TV sets or displays cannot be connected to the internet. It will be attractive to customers that TV sets or displays can be connected to the internet via their HDMI ports.

### SUMMARY OF THE INVENTION

An object of the invention is to provide a wireless network adapter which can make a network connection through the HDMI.

To accomplish the above object, the invention includes a circuit board, a wireless network module, a High Definition Multimedia Interface (HDMI) connector, and a housing. The wireless network module is electrically connected to the circuit board. The HDMI connector is electrically connected to the circuit board. The housing has a room for accommodating the circuit board, the wireless network module and a part of the HDMI connector and an opening for being protruded by the HDMI connector. The adapter can be connected to a host by the HDMI connector.

In comparison with prior art, a computer can use the present invention to connect internet through HDMI without USB. This can save a USB port of a computer for other devices. Furthermore, a TV set without a USB port or RJ45 port can connect to internet through HDMI.

### BRIEF DESCRIPTION OF THE DRAWINGS

FIG. 1 is a perspective view of a preferred embodiment of the invention;

FIG. 2 is a cross-sectional view of the embodiment shown in FIG. 1;

FIG. 3 is a schematic view of the embodiment shown in FIG. 1 and a notebook computer;

FIG. 4 1 is a perspective view of another preferred embodiment of the invention;

FIG. 5 is a cross-sectional view of the embodiment shown in FIG. 4;

FIG. 6 is a schematic view of the embodiment shown in FIG. 4 and a notebook computer; and

FIG. 7 is a schematic view of still another embodiment of the invention and a notebook computer.

### DETAILED DESCRIPTION OF THE INVENTION

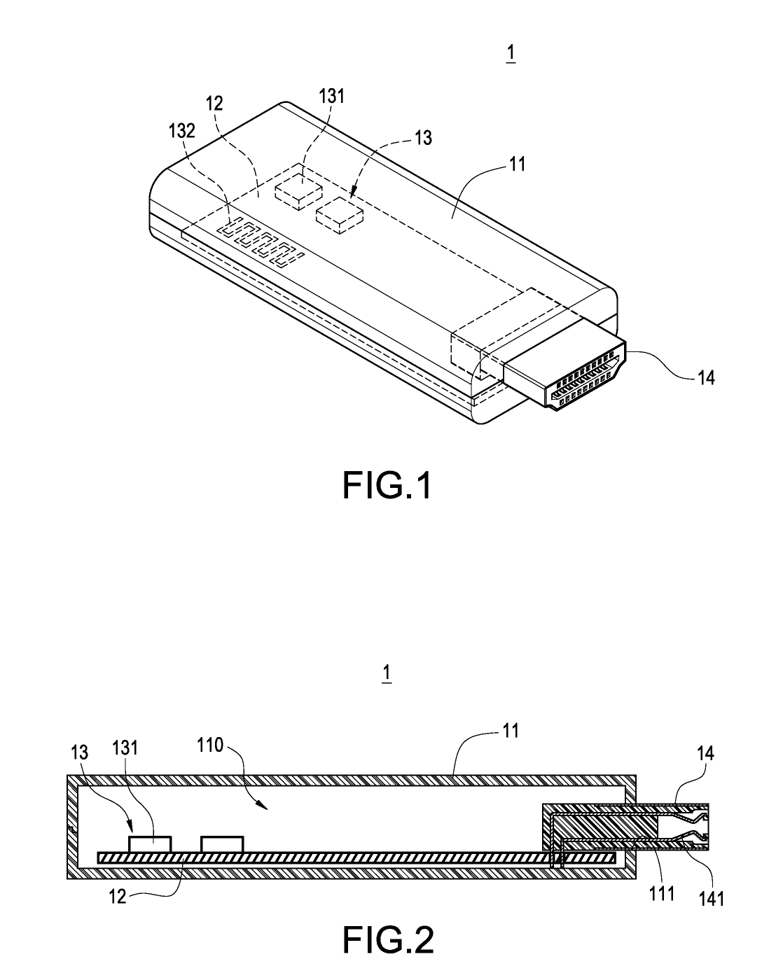

Please refer to FIG. 1. The wireless network adapter of the invention includes a housing 11, a circuit board 12, a wireless network module 13 and a High Definition Multimedia Interface (HDMI) connector 14. The wireless network module 13 further includes a wireless network processor 131 and an antenna 132.

The invention replaces the Universal Serial Bus (USB), which is commonly used by conventional wireless network adapters, with HDMI. This can save a USB port of a computer for other devices. Furthermore, a TV set without a USB port or RJ45 port can connect to internet through HDMI.

Please refer to FIG. 2. The wireless network module 13 is electrically connected to the circuit board 12. There are a plurality of pins 141 in the HDMI connector 14. The housing 11 has a room 110 for accommodating the circuit board 12, wireless network module 13 and a part of the HDMI connector 14. An end of the housing 11 is provided with a first opening 111 through which the HDMI connector 14 protrudes from the housing 11.

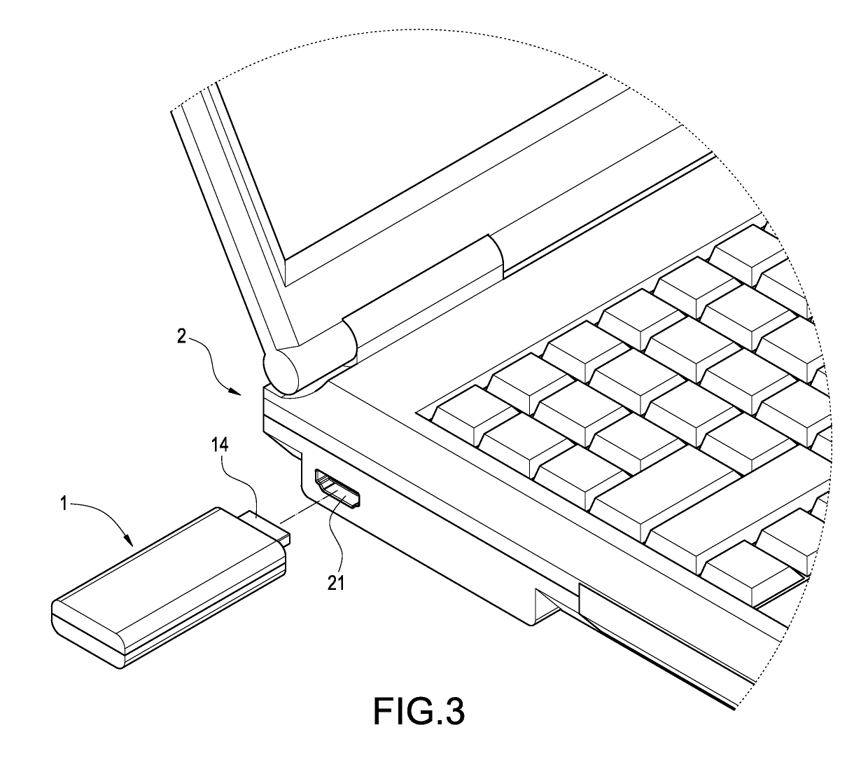

Please refer to FIG. 3. The wireless network adapter 1 may be connected to a computer 2 by inserting the HDMI connector 14 into an HDMI socket 21 of the computer 2. As a result, the computer 2 can access internet through HDMI.

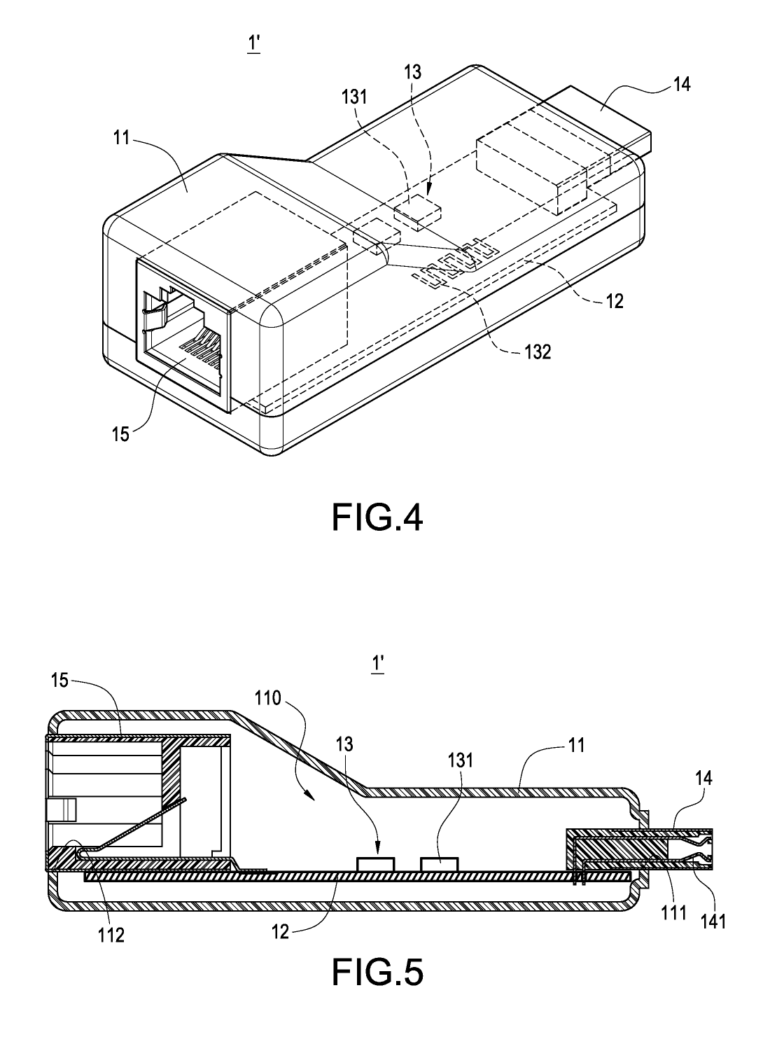

Please refer to FIGS. 4 and 5, which show another embodiment of the invention. As shown in FIGS. 4 and 5, the wireless network adapter 1′ further includes an RJ45 connector 15. The RJ45 connector 15 is electrically connected to the circuit board 12. As shown in FIG. 5, the other end of the housing 11 is provided with a second opening 112 for accommodating the RJ45 connector 15.

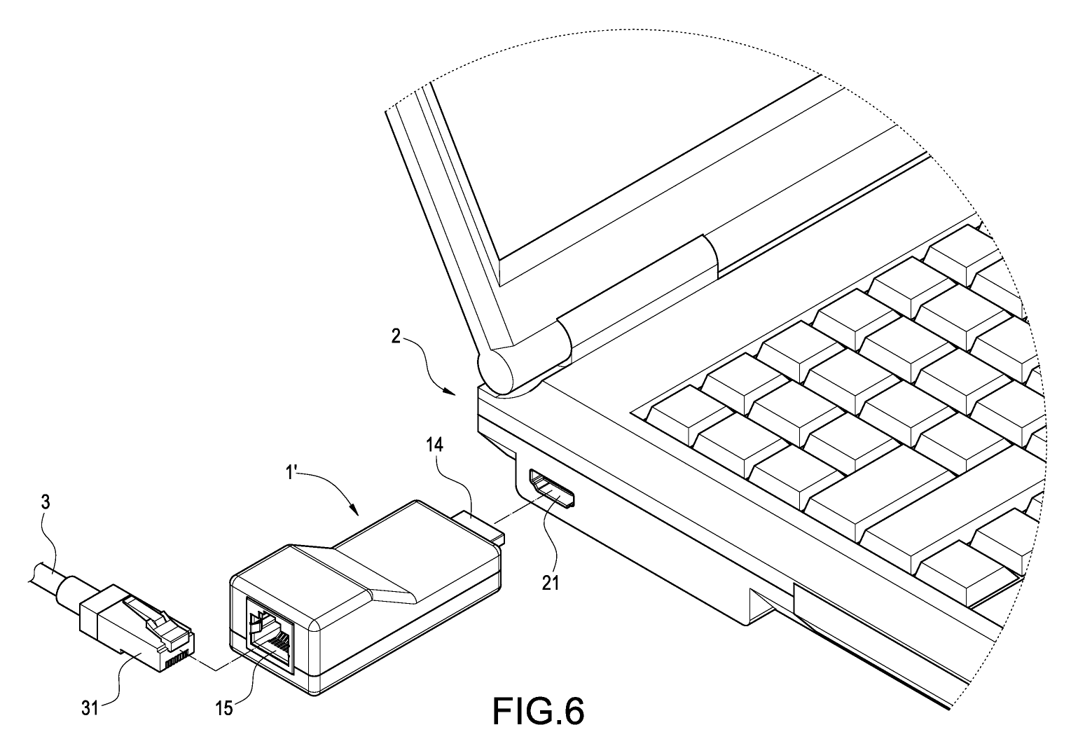

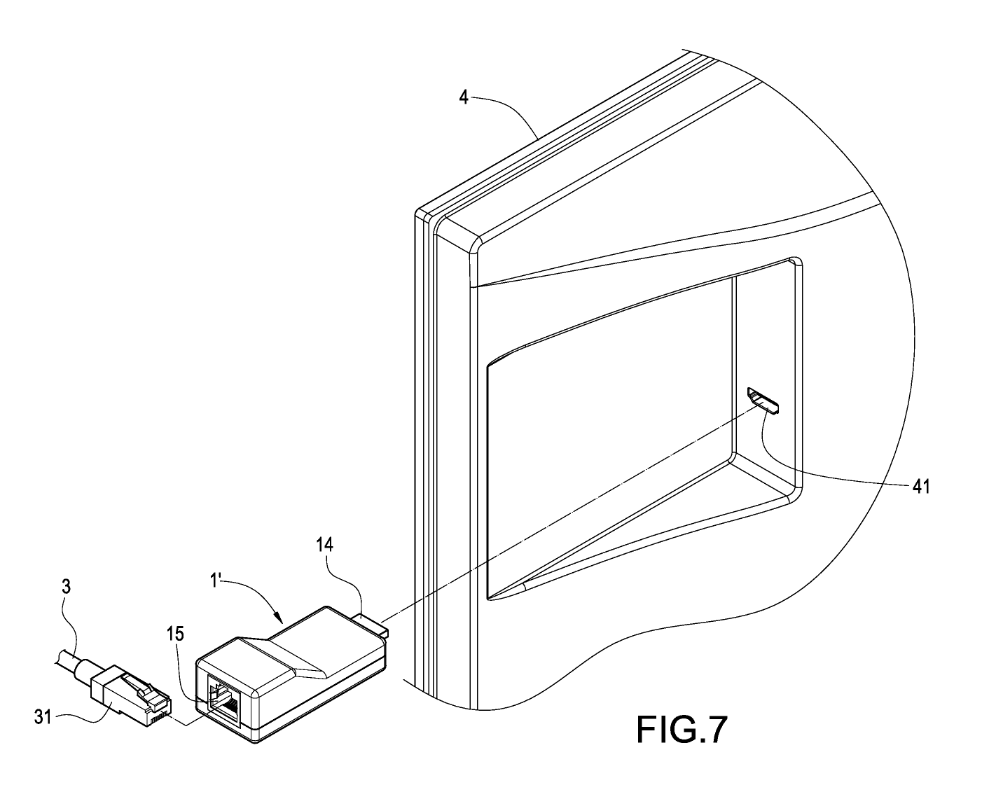

Please refer to FIG. 6. The wireless network adapter 1′ with an RJ45 connector 15 may be connected to the computer 2 through the HDMI connector 14 and the RJ45 connector 15 may be connected by a plug 31 of a cable 3. Thus, the wireless network adapter 1′ may be electrically coupled to an external device (not shown) connected with the cable 3. For example, if the external device is a second computer, then the second computer can electrically connect to the wireless network adapter 1′ via the cable 3. As a result, the second computer may access internet through the wireless network adapter 1′. That is to say, the second computer can share networking function of the wireless network adapter 1′ with the computer 2. Further, if the cable 3 is connected to a modem (not shown), the computer 2 can connect to the modem through the wireless network adapter 1′ and the cable 3. This is a wired connection.

Please refer to FIG. 7, which shows still another embodiment of the invention. The HDMI connector 14 of the wireless network adapter 1′ may be connected to an HDMI socket 41 of a playing device 4 such as an LCD TV set, such that the playing device 4 may be provided with a networking function to access internet even if it has no USB port or RJ45 port.

Further, the RJ45 connector 15 also can be inserted by the cable 3 to connect a modem. As a result, the playing device 4 can connect network through a wired way.

It will be appreciated by persons skilled in the art that the above embodiments have been described by way of example only and not in any limitative sense, and that various alterations and modifications are possible without departure from the scope of the invention as defined by the appended claims. It will be appreciated by persons skilled in the art that the above embodiment has been described by way of example only and not in any limitative sense, and that various alterations and modifications are possible without departure from the scope of the invention as defined by the appended claims.

What is claimed is:

1. A wireless network adapter comprising:
a circuit board;
a wireless network module electrically connected to the circuit board;
a High Definition Multimedia Interface (HDMI) connector electrically connected to the circuit board; and
a housing having a room for accommodating the circuit board, the wireless network module and a part of the HDMI connector and a first opening for being protruded by the HDMI connector.

2. The wireless network adapter of claim 1, wherein the wireless network module comprises a wireless network processor and an antenna.

3. The wireless network adapter of claim 2, further comprising an RJ45 connector electrically connected to the circuit board.

4. The wireless network adapter of claim 3, wherein the housing is provided with a second opening at an opposite end of the first opening for accommodating the RJ45 connector.

5. The wireless network adapter of claim 1, wherein the HDMI connector adopts a specification of HDMI version 1.4 or above.
